(19) United States
(12) Patent Application Publication
(10) Pub. No.: US 2025/0253817 A1
(43) Pub. Date: Aug. 7, 2025

(54) SINGLE DIFFERENTIAL-BASED BALANCED AMPLIFIER, OPERATION METHOD OF THE SAME, AND WIRELESS COMMUNICATION DEVICE

(71) Applicant: SAMSUNG ELECTRONICS CO., LTD., SUWON-SI (KR)

(72) Inventors: Hanwoong Choi, Suwon-si (KR); Geonho Park, Suwon-si (KR); Hyunchul Park, Suwon-si (KR); Jongwon Yun, Suwon-si (KR); Joonhoi Hur, Suwon-si (KR)

(21) Appl. No.: 19/007,635

(22) Filed: Jan. 2, 2025

(30) Foreign Application Priority Data
Feb. 6, 2024 (KR) 10-2024-0018399
Jun. 27, 2024 (KR) 10-2024-0084819

(51) Int. Cl. H03F 3/45; H04B 1/40

(52) U.S. Cl. CPC H03F 3/45475; H04B 1/40

(57) ABSTRACT

Provided is a single differential-based balanced amplifier including one differential amplifier configured to receive a first differential input signal and a second differential input signal having a phase difference of 180 degrees from the first differential input signal, and output a first differential output signal at a first output terminal and a second differential output signal at a second output terminal, a phase delay circuit configured to receive the first differential output signal, and output a third differential output signal obtained by adjusting a phase of the first differential output signal relative to the second differential output signal by 90 degrees, and a hybrid coupler configured to receive the second differential output signal at a first port, receive a third differential output signal at a third port, and output, at a second port, an in-phase signal in which RF power of the second differential output signal and the third differential output signal are combined in phase.

### CROSS-REFERENCE TO RELATED APPLICATIONS

This application is based on and claims priority under 35 U.S.C. § 119 to Korean Patent Application No. 10-2024-0018399 filed on Feb. 6, 2024 and Korean Patent Application No. 10-2024-0084819 filed on Jun. 27, 2024 in the Korean Intellectual Property office, the disclosures of which are incorporated by reference herein in their entireties.

### TECHNICAL FIELD

This disclosure relates to balanced amplifiers, differential amplifiers, and transceivers and wireless communication devices including the same.

### DISCUSSION OF RELATED ART

Recently, wireless communication systems have been implemented to perform communication in a high frequency band to achieve a high data transmission rate. For example, in 5G communication systems, beamforming, massive multi-input multi-output (MIMO), full dimensional MIMO (FD-MIMO), array antenna, analog beam-forming, or large scale antenna technology has been introduced to mitigate path loss and increase transmission distance in high frequency bands.

The wireless communication devices in these systems may include power amplifiers corresponding to different respective frequency bands to transceive signals in various frequency bands, such as those designated for long term evolution (LTE), 5th generation (5G), 6th generation (6G), and WiFi. As the frequency bands used by the wireless communication devices increases, there is a need for a plan to reduce the area of the amplifiers.

### SUMMARY

Embodiments of the inventive concept provide a single differential-based balanced amplifier and an operation method of the single differential-based balanced amplifier to reduce an area of a balanced amplifier.

According to an aspect of the inventive concept, there is provided a single differential-based balanced amplifier including one differential amplifier configured to receive a first differential input signal and a second differential input signal having a phase difference of 180 degrees from the first differential input signal, and output a first differential output signal at a first output terminal and a second differential output signal at a second output terminal, a phase delay circuit configured to receive the first differential output signal, and output a third differential output signal obtained by adjusting a phase of the first differential output signal relative to the second differential output signal by 90 degrees, and a hybrid coupler configured to receive the second differential output signal at a first port, receive a third differential output signal at a third port, and output, at a second port, an in-phase signal in which RF power of the second differential output signal and the third differential output signal are combined in phase.

According to another aspect of the inventive concept, there is provided an operation method of a single differential-based balanced amplifier including a differential amplifier, a phase delay circuit, and a hybrid coupler, the method including applying to the differential amplifier a first differential input signal and a second differential input signal having a phase difference of 180 degrees from the first differential input signal, outputting, by the differential amplifier, a first differential output signal and a second differential output signal, outputting, by the phase delay circuit, a third differential output signal having an adjusted phase by 90 degrees from a phase of the first differential output signal, and receiving, by the hybrid coupler including first through fourth ports, a third differential output signal at the first port, receiving the second differential output signal via the third port, and outputting an in-phase signal at the second port in which the second and third differential output signals are combined in phase.

According to another aspect of the inventive concept, there is provided a single differential-based balanced amplifier including one differential amplifier configured to receive a first differential input signal and a second differential input signal having a phase difference of 180 degrees from the first differential input signal, and output a first differential output signal at a first output terminal and a second differential output signal at a second output terminal, a matching network circuit configured to form output impedance of the differential amplifier, transfer the first differential output signal to the phase delay circuit, and transfer the second differential output signal to the hybrid coupler, a phase delay circuit configured to receive the first differential output signal from the differential amplifier via the matching network circuit, adjust the first differential output signal such that a phase of the first differential output signal is different from a phase of the second differential output signal by 90 degrees, and output a third differential output signal having the adjusted phase, and a hybrid coupler configured to receive the second differential output signal at a first port, receive a third differential output signal at a third port, and output, at a second port, an in-phase signal in which RF power of the second differential output signal and the third differential output signal are combined in phase.

### BRIEF DESCRIPTION OF THE DRAWINGS

Embodiments will be more clearly understood from the following detailed description taken in conjunction with the accompanying drawings in which:

FIG. 1 is a block diagram illustrating a wireless communication device according to an embodiment;

FIG. 2A is a block diagram of a single differential-based balanced amplifier according to an embodiment;

FIG. 2B is a block diagram of an operation of a single differential-based balanced amplifier, according to an embodiment;

FIG. 3 is a block diagram of a single differential-based balanced amplifier receiving a differential input signal from a single-to-differential-based transformer, according to an embodiment;

FIG. 4 is a block diagram of a single differential-based balanced amplifier including a matching network circuit, according to an embodiment;

FIG. 5 is a circuit diagram of a single differential-based balanced amplifier including a matching network circuit, according to an embodiment;

FIG. 6 is a circuit diagram of a single differential-based balanced amplifier including a matching network circuit, according to an embodiment;

FIG. 7 is a circuit diagram of a single differential-based balanced amplifier including a hybrid coupler, according to an embodiment;

FIG. 8 is a flowchart of an operation method of a single differential-based balanced amplifier, according to an embodiment;

FIG. 9 is a flowchart of an operation method of a single differential-based balanced amplifier, according to an embodiment;

FIG. 10 is a block diagram of a wireless communication device according to an embodiment; and

FIG. 11 is a conceptual diagram of an Internet of Things (IoT) network system, to which the embodiments of the inventive concept are applied.

### DETAILED DESCRIPTION OF THE EMBODIMENTS

Hereinafter, embodiments of the inventive concept are described in detail with reference to the accompanying drawings.

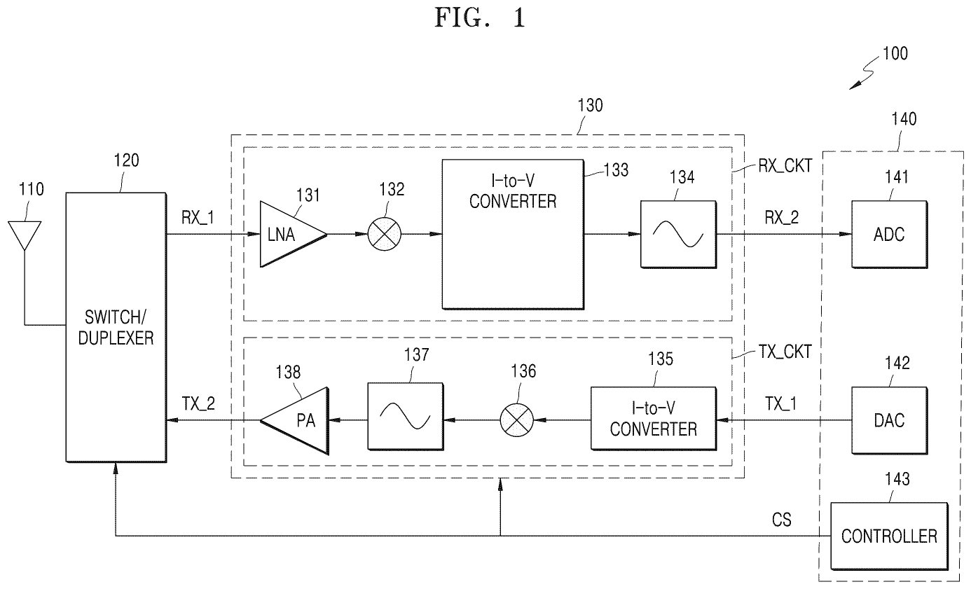

FIG. 1 is a block diagram illustrating a wireless communication device 100 according to an embodiment.

Referring to FIG. 1, wireless communication systems (not illustrated) with which the wireless communication device 100 communicates may include wireless communication systems using cellular networks, such as next-generation wireless systems, 5th generation (5G) wireless systems, long term evolution (LTE) wireless systems, LTE-advanced systems, code division multiple access (CDMA) wireless systems, global system for mobile communications (GSM) systems, and Wi-Fi systems.

Referring to FIG. 1, the wireless communication device 100 may include an antenna 110, a switch/duplexer 120, a transceiver 130, and a baseband processor 140. The wireless communication device 100 may further include components for signal transmission/reception. The switch/duplexer 120 may provide a signal received via the antenna 110 as a first reception signal RX_1 to the transceiver 130, and may also provide a second transmission signal TX_2 received from the transceiver 130 to the antenna 110.

The transceiver 130 may include a reception circuit RX_CKT (or, referred to as a receiver) and a transmission circuit TX_CKT (or, referred to as a transmitter).

The reception circuit RX_CKT may process the first reception signal RX_1 received from the switch/duplexer 120, generate a second reception signal RX_2, and provide the second reception signal RX_2 to the baseband processor 140. The reception circuit RX_CKT may include a low noise amplifier (LNA) 131, an RX mixer 132, an RX current-to-voltage (I-to-V) converter 133 (e.g., an operational amplifier for baseband signal amplification), and an RX filter 134, to process the first reception signal RX_1. The LNA 131 may amplify the input signal to generate an output signal, the RX mixer 132 may perform frequency down conversion on an input signal of a first radio frequency (RF) band to generate an output signal of a baseband, the I-to-V converter 133 may generate an input signal corresponding to a current signal as an output signal corresponding to a voltage signal, and the RX filter 134 may generate an output signal by removing undesired portions from the input signal.

The transmission circuit TX_CKT may generate the second transmission signal TX_2 and provide the second transmission signal TX_2 to the switch/duplexer 120 by processing a first transmission signal TX_1 received from the baseband processor 140. The transmission circuit TX_CKT may include a TX current-to-voltage converter (I-to-V) 135, a TX mixer 136, a TX filter 137, and a power amplifier (PA) 138 to process the first transmission signal TX_1. The I-to-V converter 135 may generate an input signal corresponding to a current signal as an output signal corresponding to a voltage signal, the TX mixer 136 may perform frequency up-conversion process on the input signal to generate an output signal of a second RF band, the TX filter 137 may generate an output signal by removing unwanted portions from the input signal, and the PA 138 may amplify the input signal to generate an output signal.

In a particular mode, for example, in a frequency division duplex (FDD) mode, in the wireless communication device 100, the reception circuit RX_CKT and the transmission circuit TX_CKT may simultaneously perform reception and transmission by using different RF bands. The reception circuit RX_CKT may process the first reception signal RX_1 of the first RF band to generate the second reception signal RX_2 of the baseband, and at the same time, the transmission circuit TX_CKT may process the first transmission signal TX_1 of the baseband to generate the second transmission signal TX_2 of the second RF band. A frequency distance between the first RF band and the second RF band in the FDD mode may be defined as a transmission/reception frequency offset. In some embodiments, in a time division duplex (TDD) mode, in the wireless communication device 100, the reception circuit RX_CKT and the transmission circuit TX_CKT may also alternately perform reception and transmission over time, respectively, and in this case, the first RF band may be the same as the second RF band.

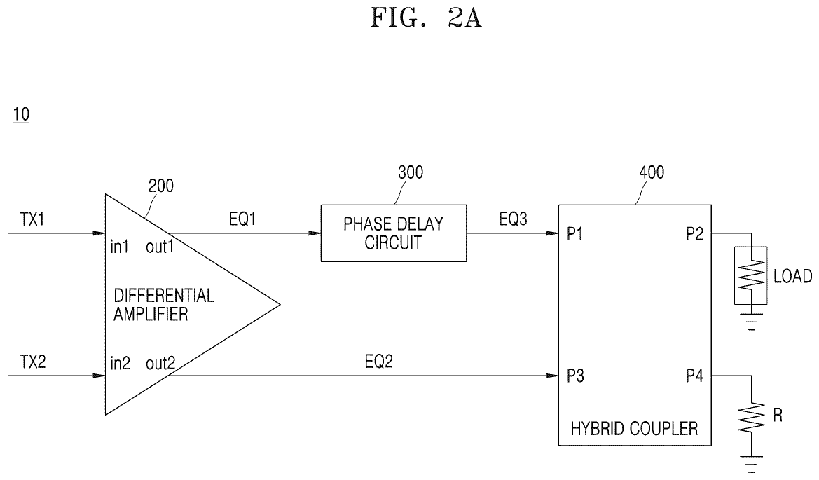

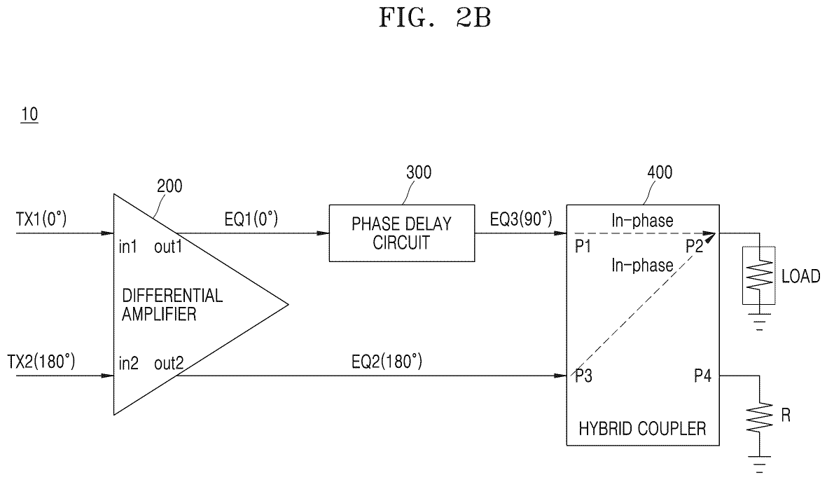

The PA 138 may include the single differential-based balanced amplifier according to embodiments of the inventive concept described below with reference to FIGS. 2 through 7. The single differential-based balanced amplifier according to the embodiment may include one differential amplifier configured to receive a first differential input signal and a second differential input signal having a phase difference of 180 degrees from the first differential input signal, and output a first differential output signal at a first output terminal and a second differential output signal at a second output terminal; a phase delay circuit configured to receive the first differential output signal, and output a third differential output signal obtained by adjusting a phase of the first differential output signal relative to the second differential output signal by 90 degrees; and a hybrid coupler 400 configured to receive the second differential output signal at a first port, and the third differential output signal at a third port, and output, at a second port, an in-phase signal in which RF power of the second differential output signal and the third differential output signal are combined in phase. A phase difference between the second differential output signal and the third differential output signal may be 90 degrees. The single differential-based balanced amplifier may further include a transformer which receives an RF signal, converts the RF signal into the first differential input signal and the second differential input signal, and outputs the first differential input signal and the second differential input signal to the differential amplifier. The single differential-based balanced amplifier may further include the matching network circuit which is arranged between the differential amplifier and the hybrid coupler, and forms an output impedance of the differential amplifier. The output impedance may have a value such that mismatch loss (due to VSWR) between the output of the differential amplifier 200 and the hybrid coupler 400 is minimized. A first differential output signal may be transmitted to the phase delay circuit via the matching network circuit, and a second differential output signal may be transmitted to the third port of the hybrid coupler via the matching network circuit. A fourth port of the hybrid coupler may be isolated.

For example, the matching network circuit may include a first inductor, a second inductor, a third inductor, and a fourth inductor. The first inductor may be connected between the first output terminal from which the first differential output signal of the differential amplifier is output and a first center node, the second inductor may be connected between the second output terminal from which the second output differential signal of the differential amplifier is output and the first center node, the third inductor may be connected between a second center node and an input node of the phase delay circuit, one end of the fourth inductor may be connected to the second center node, and the other end of the fourth inductor may be connected to the third port of the hybrid coupler. A supply voltage VDD may be applied to the first center node. In addition, the phase delay circuit may include a first phase delay capacitor, a second phase delay capacitor, and a phase delay inductor. The first phase delay capacitor may be connected between an input node of the phase delay circuit and a ground, one end of the second phase delay capacitor may be connected to the first port of the hybrid coupler, the other end of the hybrid coupler may be connected to the ground, one end of the phase delay inductor may be connected to the input node of the phase delay circuit, and the other end of the phase delay inductor may be connected to the first port of the hybrid coupler. In addition, the hybrid coupler may include a first coupler capacitor, a second coupler capacitor, a first coupler inductor, and a second coupler inductor. The first coupler capacitor may be connected between the first port and the third port, the second coupler capacitor may be connected between the second port and the fourth port, the first coupler inductor may be connected between the third port and the fourth port, and the second coupler inductor may be connected between the first port and the second port.

As another example, the matching network circuit may include the first inductor, the second inductor, a first capacitor, and a second capacitor. The first inductor may be connected between the first output terminal and the first center node, the second inductor may be connected between the second output terminal and the first center node, the first capacitor may be connected between the first output terminal and the input node of the phase delay circuit, one end of the second capacitor may be connected to the second output terminal, and the other end of the second capacitor may be connected to the third port of the hybrid coupler. The supply voltage VDD may be applied to the first center node. In addition, the phase delay circuit may include the first phase delay capacitor, the second phase delay capacitor, and the phase delay inductor. The first phase delay capacitor may be connected between an input node of the phase delay circuit and the ground, one end of the second phase delay capacitor may be connected to the first port of the hybrid coupler, the other end of the hybrid coupler may be connected to the ground, one end of the phase delay inductor may be connected to the input node of the phase delay circuit. In addition, the hybrid coupler may include the first coupler capacitor, the second coupler capacitor, the first coupler inductor, and the second coupler inductor. The first coupler capacitor may be connected between the first port and the third port, the second coupler capacitor may be connected between the second port and the fourth port, the first coupler inductor may be connected between the third port and the fourth port, and the second coupler inductor may be connected between the first port and the second port.

As another example, the hybrid coupler may include first through fourth coupler capacitors and first through sixth coupler inductors. The first coupler capacitor may be connected between the first port and the third port, the second coupler capacitor may be connected between the second port and the fourth port, one end of the third coupler capacitor may be connected to one end of the sixth coupler inductor, the other end of the third coupler capacitor may be connected to the fourth port, one end of the fourth coupler capacitor may be connected to one end of the fifth coupler inductor, and the other end of the fourth coupler capacitor may be connected to the second port. One end of the first coupler inductor may be connected to the third port, a supply power source may be applied to the other end of the first coupler inductor, one end of the second coupler inductor may be connected to the second port, a supply power source may be applied to the other end of the second coupler inductor, the third coupler inductor may be connected between the fourth port and the ground, the fourth coupler inductor may be connected between the second port and the ground, one end of the fifth coupler inductor may be connected to the third port, the other end of the fifth coupler inductor may be connected to one end of the fourth coupler capacitor, one end of the sixth coupler inductor may be connected to the first port, and the other end of the sixth coupler inductor may be connected to the third coupler capacitor.

Because a single differential-based balanced amplifier according to an embodiment operates based on one differential amplifier, the single differential-based balanced amplifier may omit a power distributor. This reduces circuit complexity as compared to a balanced amplifier using two differential amplifiers, which includes a power distributor for distributing power to be supplied to the differential amplifiers.

Because the single differential-based balanced amplifier according to an embodiment operates based on one differential amplifier, the area used by the differential amplifier in the wireless communication device 100 may be reduced.

Because the single differential-based balanced amplifier according to an embodiment operates based on one differential amplifier, it may be possible to stably create a virtual ground.

The single differential-based balanced amplifier according to an embodiment may, by arranging a hybrid coupler between an antenna and a differential amplifier, have an antenna resilient characteristic and may be insensitive to antenna voltage standing wave ratio (VSWR) changes.

FIG. 2A is a block diagram of a single differential-based balanced amplifier 10 according to an embodiment.

Referring to FIG. 2A, the single differential-based balanced amplifier 10 according to the inventive concept may include a differential amplifier 200, a phase delay circuit 300, and a hybrid coupler 400. The single differential-based balanced amplifier 10 according to the inventive concept may include one differential amplifier, unlike a general balanced amplifier which includes two differential amplifiers.

Some examples of the hybrid coupler 400 may include a 90-degree hybrid coupler, a 180-degree hybrid coupler (e.g., a “rat race”), and a Lange coupler. According to an embodiment, the hybrid coupler 400 may include the 90-degree hybrid coupler, and may be referred to as a 90-degree hybrid, a quadrature signal distributor, a branch-line hybrid, etc. In the following description, it is assumed that the hybrid coupler 400 is the 90-degree hybrid coupler and embodiments are accordingly described below.

The differential amplifier 200 may receive a first differential input signal TX1 and a second differential input signal TX2, and output a first differential output signal EQ1 and a second differential output signal EQ2. The second differential input signal TX2 may be the same signal as the first differential input signal TX1, with equal RF power but with opposite phase (180 degrees out of phase).

The phase delay circuit 300 may receive the first differential output signal EQ1. The phase delay circuit 300 may receive the first differential output signal EQ1, and output a third differential output signal EQ3 of which a phase is delayed from the first differential output signal. The phase delay circuit 300 may adjust the phase of the third differential output signal EQ3 so that the hybrid coupler 400 transmits an “in-phase” output signal to a load. For example, the phase delay circuit 300 may adjust the phase of the third differential output signal EQ3 so that the phase difference between the second differential output signal EQ2 and the third differential output signal EQ3, which are input to the hybrid coupler 400, is 90 degrees. According to another embodiment, when the hybrid coupler 400 is not the 90-degree hybrid coupler, the phase delay circuit 300 may appropriately adjust the phase of the third differential output signal EQ3 so that the hybrid coupler 400 transmits an in-phase output signal to a load. In either of the two scenarios, in an ideal case, the in-phase output signal may have RF power equaling the sum of the RF powers of the second and third differential output signals EQ2 and EQ3. In practice, some mismatch loss due to standing waves (VSWR), and I²R loss, may result in the in-phase output signal having slightly less RF power than the sum of the second and third differential output signals EQ2 and EQ3.

The hybrid coupler 400 may receive the second differential output signal EQ2 and the third differential output signal EQ3. The third differential output signal EQ3 may be applied to a first port P1, and the second differential output signal EQ2 may be applied to a third port P3. The hybrid coupler 400 may transmit an output signal in which the second differential output signal EQ2 and the third differential output signal EQ3 are in-phase with each other, to a load connected to a second port P2. In addition, the hybrid coupler 400 may transmit an output signal in which the second differential output signal EQ2 and the third differential output signal EQ3 are out-of-phase with respect to each other, to a resistor R connected to a fourth port P4. Accordingly, the fourth port P4 may be isolated. According to an embodiment, resistance of the resistor R may be 50 ohms. In an ideal case, zero RF power flows to the resistor R. In practice, due to mismatch loss, a small amount of RF power may flow to the resistor R.

The single differential-based balanced amplifier 10 according to an embodiment may include the differential amplifier 200 which receives two differential input signals having a phase difference of 180 degrees from each other, and the phase delay circuit 300 which delays a phase of one of the output signals of the differential amplifier 200 by 90 degrees. The single differential-based balanced amplifier 10 according to an embodiment may generate signals input to the hybrid coupler 400, by adjusting a difference between the phases of the first differential output signal EQ1 and the second differential output signal EQ2, which are the output signals of the differential amplifier 200, to 90 degrees. Accordingly, the single differential-based balanced amplifier 10 may amplify the RF signal based on one differential amplifier 200 and one hybrid coupler 400.

The single differential-based balanced amplifier 10 according to an embodiment may, by arranging the hybrid coupler 400 between an antenna and the differential amplifier 200, have an antenna resilient characteristic and may have tolerance to antenna VSWR changes.

FIG. 2B is a block diagram of an operation of the single differential-based balanced amplifier 10, according to an embodiment.

FIG. 2B may be described with reference to FIG. 2A, and duplicate descriptions thereof may be omitted. FIG. 2B shows the operation of the single differential-based balanced amplifier 10 when the first differential input signal TX1 and the second differential input signal TX2 having a phase difference of 180 degrees from each other are applied to the differential amplifier 200, as an embodiment.

Referring to FIG. 2B, the differential amplifier 200 according to an embodiment may receive the first differential input signal TX1 of a phase of 0° and the second differential input signal TX2 of a phase of 180°. The differential amplifier 200 may receive the first differential input signal TX1 of a phase 0° and the second differential input signal TX2 of a phase of 180°, and output the first differential output signal EQ1 of a phase 0° and the second differential output signal EQ2 of a phase of 180°. (Note that “a phase of 0°” is just a reference phase at the circuit point being described, e.g., the input terminals or the output terminals of the differential amplifier 200, and “a phase of 180°” or the like at the same circuit point is referenced to the reference phase at that circuit point. In addition, it may be assumed in the descriptions herein that that the transmission paths connecting the various components have zero electrical lengths, such that the desired phase relationships between the signals discussed are not impacted by unequal transmission paths.) The phase delay circuit 300 may receive the first differential output signal EQ1 of a phase of 0°. The phase delay circuit 300 may receive the first differential output signal EQ1 of a phase of 0° and output the third differential output signal EQ3 of phase 90 degrees (e.g., by delaying the signal EQ1 by) 270° from the first differential output signal EQ1 of a phase 0°. The hybrid coupler 400 may receive the second differential output signal EQ2 of a phase of 180° and the third differential output signal EQ3 of a phase of 90°. The third differential output signal EQ3 of a phase of 90° may be applied to the first port P1, and the second differential output signal EQ2 of a phase of 180° may be applied to the third port P3. The hybrid coupler 400 may generate an output signal in which the second differential output signal EQ2 of a phase of 180° and the third differential output signal EQ3 of a phase of 90° are in-phase (i.e., summed in-phase), to the load connected to the second port P2. (Note that the insertion phase from port P3 to port P2 is 90° longer than that from port P1 to port P2, resulting in the desired summing of the signals EQ2 and EQ3 at port P2. Likewise, the insertion phase from port P1 to port P4 is 90° longer than that from port P3 to port P4, resulting in cancellation of signals to port P4, whereby port P4 is an isolation port.) In addition, the hybrid coupler 400 may transmit an output signal in which the second differential output signal EQ2 of a phase of 180° and the third differential output signal EQ3 of a phase of 90° are out-of-phase with respect to each other, to the resistor R connected to the fourth port P4. Accordingly, the fourth port P4 may be isolated (so ideally zero RF power appears at the fourth port P4). According to an embodiment, resistance of the resistor R may be 50 ohms.

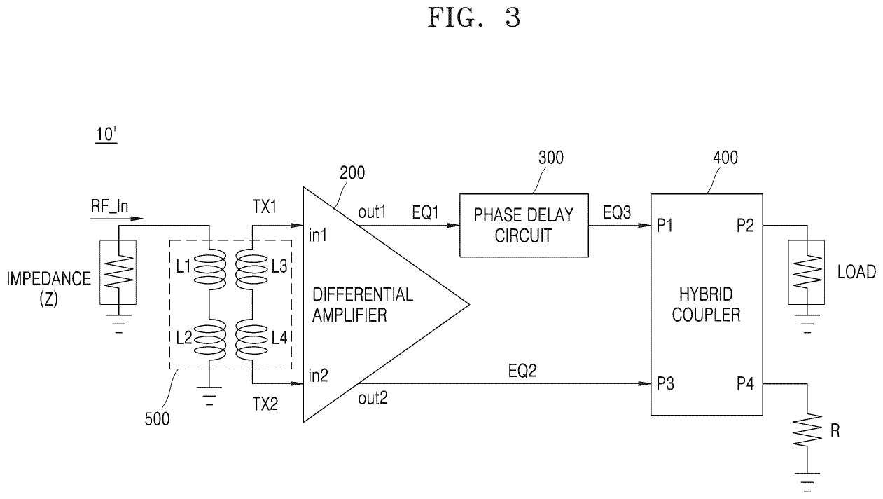

FIG. 3 is a block diagram of a single differential-based balanced amplifier 10′ receiving a differential input signal from a single-to-differential-based transformer, according to an embodiment.

FIG. 3 may be described with reference to FIG. 2A, and thus, duplicate descriptions thereof may be omitted. The single differential-based balanced amplifier 10′ according to the inventive concept may include the differential amplifier 200, the phase delay circuit 300, and the hybrid coupler 400. The single differential-based balanced amplifier 10′ may further include a transformer 500 for converting the RF signal into the first differential input signal TX1 and the second differential input signal TX2.

The transformer 500 may include first through fourth inductors L1 through L4. The transformer 500 may convert an RF input signal RF_In applied from a transmission line or an antenna into the first differential input signal TX1 and the second differential input signal TX2. A phase difference between the first differential input signal TX1 and the second differential input signal TX2 may be 180 degrees.

The transformer 500 according to the embodiment of FIG. 3 may include a single-to-differential-based transformer, but is not limited thereto. According to other embodiments, the single-to-differential-based transformer may be substituted with a differential-to-differential-based transformer.

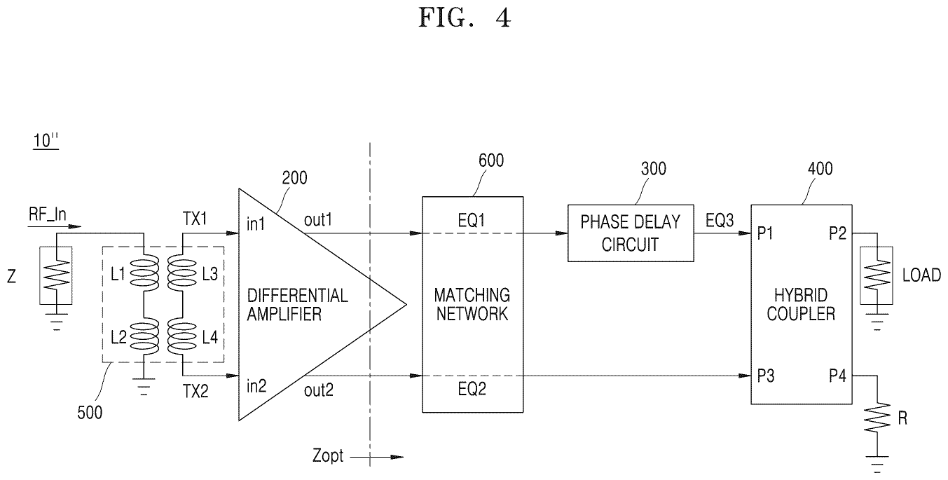

FIG. 4 is a block diagram of the single differential-based balanced amplifier 10″ including a matching network circuit 600, according to an embodiment.

FIG. 4 may be described with reference to FIGS. 2A and 3, and duplicate descriptions thereof may be omitted. The single differential-based balanced amplifier 10″ according to the inventive concept may include the differential amplifier 200, the phase delay circuit 300, the hybrid coupler 400, and the transformer 500.

Referring to FIG. 4, the single differential-based balanced amplifier 10″ may further include a matching network circuit 600. The single differential-based balanced amplifier 10″ may adjust output impedance Zₒₚₜ, viewed from an output terminal of the differential amplifier 200, that changes according to frequency by using the matching network circuit 600. The matching network circuit 600 may be arranged between the differential amplifier 200 and the hybrid coupler 400, and may form an output impedance Zₒₚₜ of the differential amplifier 200. The output impedance may be such that mismatch loss (due to VSWR) between the output of the differential amplifier 200 and the hybrid coupler 400 is minimized and/or optimized over a target range of frequencies. In other words, the output impedance Zₒₚₜ may be an optimized output impedance.

The single differential-based balanced amplifier 10″ according to an embodiment may include one differential amplifier 200 configured to receive the first differential input signal and the second differential input signal having a phase difference of 180 degrees from the first differential input signal, and output the first differential output signal at the first output terminal and the second differential output signal at the second output terminal. The matching network circuit 600 may be configured to form output impedance of the differential amplifier 200, transfer the first differential output signal EQ1 to the phase delay circuit 300, and transfer the second differential output signal EQ2 to the hybrid coupler 400. The phase delay circuit 300 may be configured to receive the first differential output signal from the differential amplifier 200 via the matching network circuit 600, adjust the phase of the first differential output signal to have a phase difference of 90 degrees from the phase of the second differential output signal, and output the third differential output signal of the adjusted phase, and the hybrid coupler 400 configured to receive the second differential output signal from the first port P1, receive the third differential output signal from the third port P3, and output an in-phase signal in which RF power of the second differential output signal and the third differential output signal are combined in phase, from the second port P2. The fourth port P4 of the hybrid coupler 400 may be isolated. The single differential-based balanced amplifier 10″ may further include the transformer 500 which receives the RF signal, converts the RF signal into the first differential input signal and the second differential input signal, and outputs the first differential input signal and the second differential input signal to the differential amplifier 200.

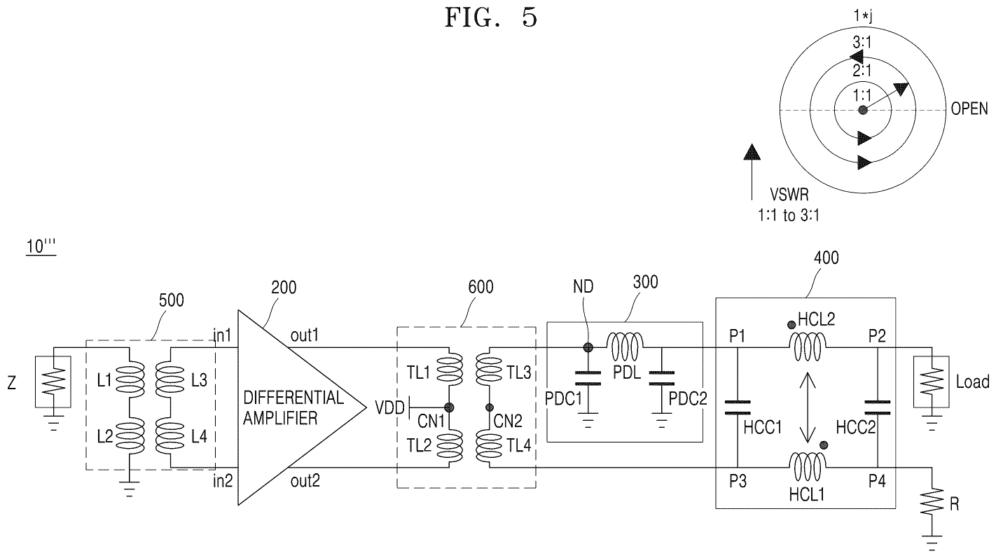

Referring temporarily to FIG. 5, according to an embodiment, the matching network circuit 600 may include inductors TL1 to TL4 described below in connection with FIG. 5. The inductor TL1 may be connected between the first output terminal from which the first differential output signal of the differential amplifier is output and a first center node CN1, the inductor TL2 may be connected between the second output terminal from which the second output differential signal of the differential amplifier is output and the first center node CN1, the inductor TL3 may be connected between a second center node CN2 and an input node ND of the phase delay circuit, one end of the inductor TL4 may be connected to the second center node CN2, and the other end of the inductor TL4 may be connected to the a third port P3 of the hybrid coupler 400. A supply voltage VDD may be applied to the first center node CN1.

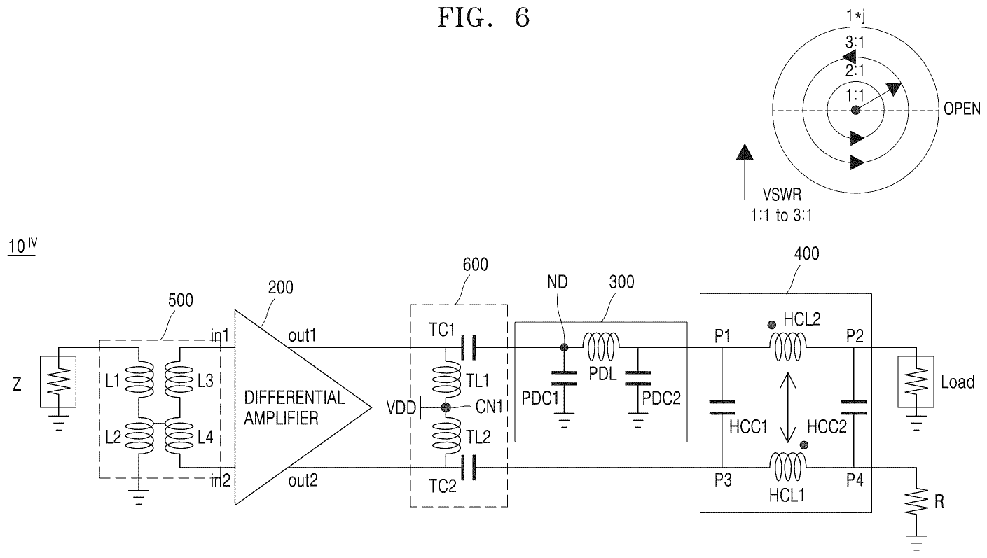

Referring temporarily to FIG. 6, according to another embodiment, the matching network circuit 600 may include the inductors TL1 and TL2, a first capacitor TC1, and a second capacitor TC2. The inductor TL1 may be connected between the first output terminal and the first center node, the inductor TL2 may be connected between the second output terminal and the first center node, the first capacitor may be connected between the first output terminal and the input node of the phase delay circuit, one end of the second capacitor may be connected to the second output terminal, and the other end of the second capacitor may be connected to the third port P3 of the hybrid coupler 400. The supply voltage VDD may be applied to the first center node. In addition, the phase delay circuit 300 may include a first phase delay capacitor PDC1, a second phase delay capacitor PDC2, and a phase delay inductor PDL. The first phase delay capacitor may be connected between the input node of the phase delay circuit 300 and ground, one end of the second phase delay capacitor may be connected to the first port P1 of the hybrid coupler 400, the other end of the hybrid coupler 400 may be connected to the ground, one end of the phase delay inductor may be connected to the input node of the phase delay circuit 300, and the other end of the phase delay inductor may be connected to the first port P1 of the hybrid coupler 400. In addition, the hybrid coupler 400 may include a first coupler capacitor HCC1, a second coupler capacitor HCC2, a first coupler inductor HCL1, and a second coupler inductor HCL2. The first coupler capacitor may be connected between the first port P1 and the third port P3, the second coupler capacitor may be connected between the second port P2 and the fourth port P4, the first coupler inductor may be connected between the third port P3 and the fourth port P4, and the second coupler inductor may be connected between the first port P1 and the second port P2.

FIG. 5 is a circuit diagram of a single differential-based balanced amplifier 10″ including the matching network circuit 600 and an example configuration of the phase delay circuit 300, according to an embodiment.

FIG. 5 may be described with reference to FIGS. 2A, 3, and 4, and duplicate descriptions thereof may be omitted. According to an embodiment, the matching network circuit 600 in FIG. 5 may include a differential-to-differential transformer.

The matching network circuit 600 may include first through fourth inductors TL1 through TL4. The phase delay circuit 300 may include capacitors PDC1 and PDC2, and an inductor PDL. Herein, the capacitor PDC1 may be referred to as the first phase delay capacitor, the capacitor PDC2 may be referred to as the second phase delay capacitor, and the inductor PDL may be referred to as the phase delay inductor. The hybrid coupler 400 may include capacitors HCC1 and HCC2, and inductors HCL1 and HCL2. In this description, the capacitor HCC1 may be referred to as the first coupler capacitor, the capacitor HCC2 may be referred to as the second coupler capacitor, the inductor HCL1 may be referred to as the first coupler capacitor, and the inductor HCL2 may be referred to as the second coupler inductor.

The supply voltage VDD may be applied to a first center node CN1 of the matching network circuit 600. Accordingly, transistors inside the differential amplifier 200 may operate. A first inductor TL1 of the matching network circuit 600 may be connected between a first output terminal out1 of the differential amplifier 200 and the first center node CN1. A second inductor TL2 may be connected between a second output terminal out2 and the first center node CN1. A third inductor TL3 may be connected between a second center node CN2 and a node ND. The node ND may be an input node of the phase delay circuit 300. One end of a fourth inductor TL4 may be connected to the second center node CN2, and the other end thereof may be connected to the third port P3 of the hybrid coupler 400.

The capacitor PDC1 of the phase delay circuit 300 may be connected between the node ND and the ground. One end of the capacitor PDC2 may be connected to the first port P1 of the hybrid coupler 400, and the other end thereof may be connected to the ground. One end of the inductor PDL may be connected to the node ND, and the other end thereof may be connected to the first port P1 of the hybrid coupler 400.

The capacitor HCC1 of the hybrid coupler 400 may be connected between the first port P1 and the third port P3. The capacitor HCC2 may be connected between the second port P2 and the fourth port P4. The inductor HCL1 may be connected between the third port P3 and the fourth port P4. The inductor HCL2 may be connected between the first port P1 and the second port P2.

FIG. 6 is a block diagram of a single differential-based balanced amplifier 10^{IV} including the matching network circuit 600, according to an embodiment.

FIG. 6 may be described with reference to FIGS. 2A, 3, 4, and 5, and duplicate descriptions thereof may be omitted. According to the embodiment, the matching network circuit 600 in FIG. 6 may include shunt inductors (for example, the first and second inductors TL1 and TL2) and series capacitors (for example, first and second capacitors TC1 and TC2).

The matching network circuit 600 may include the first and second inductors TL1 and TL2, and the first and second capacitors TC1 and TC2. The phase delay circuit 300 may include the capacitors PDC1 and PDC2, and the inductor PDL. The hybrid coupler 400 may include the capacitors HCC1 and HCC2, and the inductors HCL1 and HCL2.

The supply voltage VDD may be applied to the first center node CN1 of the matching network circuit 600. Accordingly, transistors inside the differential amplifier 200 may operate. The first inductor TL1 may be connected between the first output terminal out1 of the differential amplifier 200 and the first center node CN1. The second inductor TL2 may be connected between the second output terminal out2 and the first center node CN1. The first capacitor TC1 may be connected between the first output terminal out1 and the node ND. The node ND may be the input node of the phase delay circuit 300. One end of the second capacitor TC2 may be connected between the second output terminal out2, and the other end thereof may be connected to the third port P3 of the hybrid coupler 400.

The capacitor PDC1 of the phase delay circuit 300 may be connected between the node ND and the ground. One end of the capacitor PDC2 may be connected to the first port P1 of the hybrid coupler 400, and the other end thereof may be connected to the ground. One end of the inductor PDL may be connected to the node ND, and the other end thereof may be connected to the first port P1 of the hybrid coupler 400.

The capacitor HCC1 of the hybrid coupler 400 may be connected between the first port P1 and the third port P3. The capacitor HCC2 may be connected between the second port P2 and the fourth port P4. The inductor HCL1 may be connected between the third port P3 and the fourth port P4. The inductor HCL2 may be connected between the first port P1 and the second port P2.

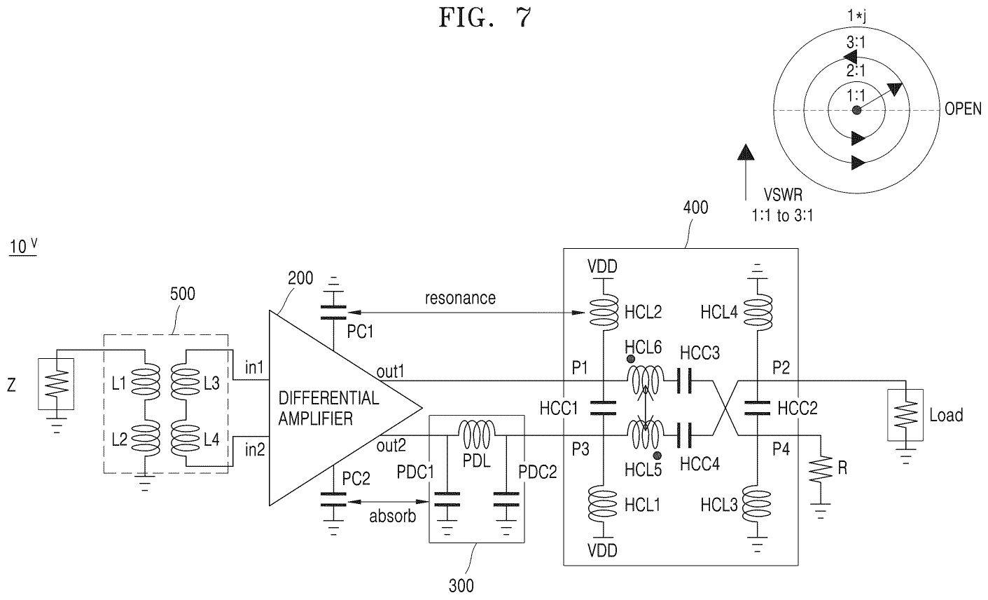

FIG. 7 is a circuit diagram of a single differential-based balanced amplifier 10^{V} including the hybrid coupler 400, according to an embodiment.

FIG. 7 may be described with reference to FIGS. 2A, 3, 4, and 5, and duplicate descriptions thereof may be omitted. The single differential-based balanced amplifier 10^{V} according to the inventive concept may include the differential amplifier 200, the phase delay circuit 300, the hybrid coupler 400, and the transformer 500. The single differential-based balanced amplifier 10^{V} may include the hybrid coupler 400 including a matching network instead of the matching network circuit 600. The hybrid coupler 400 according to an embodiment of FIG. 7 may include a matching network.

Referring to FIG. 7, the capacitor PDC1 of the phase delay circuit 300 may be connected between the second output terminal out2 of the differential amplifier 200 and the ground. One end of the capacitor PDC2 may be connected to the third port P3 of the hybrid coupler 400, and the other end thereof may be connected to the ground. One end of the inductor PDL may be connected to the second output terminal out2 of the differential amplifier 200, and the other end thereof may be connected to the third port P3 of the hybrid coupler 400.

The hybrid coupler 400 may include capacitors HCC1 through HCC6, and inductors HCL1 through HCL4. Herein, the capacitor HCC1 may be referred to as the first coupler capacitor, the capacitor HCC2 to the second coupler capacitor, the capacitor HCC3 to the third coupler capacitor, the capacitor HCC4 to the fourth coupler capacitor, the inductor HCL1 to the first coupler inductor, the inductor HCL2 to the second coupler inductor, the inductor HCL3 to the third coupler inductor, the inductor HCL4 to the fourth coupler inductor, the inductor HCL5 to the fifth coupler inductor, and the inductor HCL1 may be referred to as the sixth coupler inductor.

The capacitor HCC1 of the hybrid coupler 400 may be connected between the first port P1 and the third port P3. The capacitor HCC2 may be connected between the second port P2 and the fourth port P4. One end of the capacitor HCC3 may be connected to one end of the inductor HCL6, and the other end thereof may be connected to the fourth port P4. One end of the capacitor HCC4 may be connected to one end of the inductor HCL5, and the other end thereof may be connected to the second port P2. One end of the inductor HCL1 may be connected to the third port P3, and a supply power source VDD may be applied to the other end thereof. One end of the inductor HCL2 may be connected to the first port P1, and the supply power source VDD may be applied to the other end thereof. The inductor HCL3 may be connected between the fourth port P4 and the ground. The inductor HCL4 may be connected between the second port P2 and the ground. One end of the inductor HCL5 may be connected to the third port P3, and the other end thereof may be connected to one end of the capacitor HCC4. One end of the inductor HCL6 is connected to the first port P1 and the other end thereof may be connected to the capacitor HCC3.

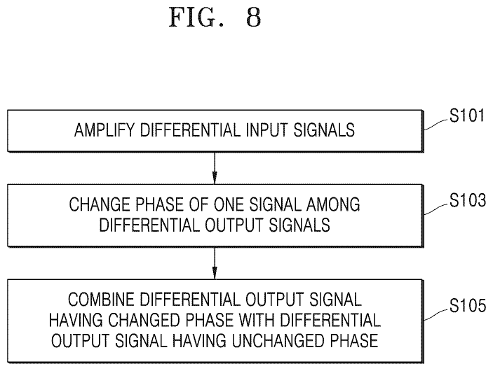

FIG. 8 is a flowchart of an operation method of any of the single differential-based balanced amplifiers 10 to 10^{V}, according to an embodiment.

FIG. 8 may be described with reference to FIGS. 2A through 7. Referring to FIG. 8, in operation S101, the differential amplifier 200 of the single differential-based balanced amplifier 10 (or 10′ to 10^{V}) may amplify differential input signals.

In operation S103, the single differential-based balanced amplifier 10 (or 10′ to 10^{V}) may change a phase of one of differential output signals.

In operation S105, the single differential-based balanced amplifier 10 (or 10′ to 10^{V}) may combine the differential output signal having changed phase thereof with the differential output signal having unchanged phase thereof.

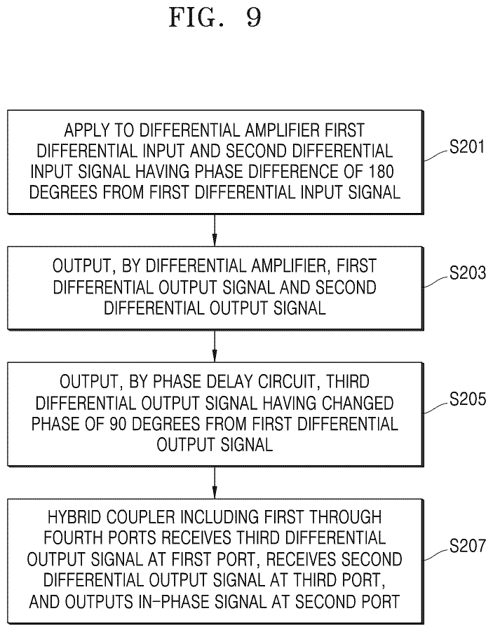

FIG. 9 is a flowchart of an operation method of any of the single differential-based balanced amplifiers 10 to 10^{V}, according to an embodiment.

FIG. 9 may be described with reference to FIGS. 2A through 7. Referring to FIG. 9, in operation S201, the first differential input signal and the second differential input signal having a phase difference of 180 degrees from the first differential input signal may be applied to the differential amplifier 200.

In operation S203, the differential amplifier 200 may output the first differential output signal and the second differential output signal.

In operation S205, the phase delay circuit 300 may output the third differential output signal having changed phase of 90 degrees from the first differential output signal. For example, the phase delay circuit 300 may adjust the phase of the first differential output signal by 90 degrees (e.g., by delaying phase by 270 degrees) so that a phase difference between the second differential output signal and the third differential output signal becomes 90 degrees. Accordingly, the phase difference between the second differential output signal and the third differential output signal may be 90 degrees.

In operation S207, the hybrid coupler 400 including the first through fourth ports P1 through P4 may receive the third differential output signal from the first port P1, receive the second differential output signal from the third port P3, and output an in-phase signal from the second port P2. The fourth port P4 of the hybrid coupler 400 may be isolated.

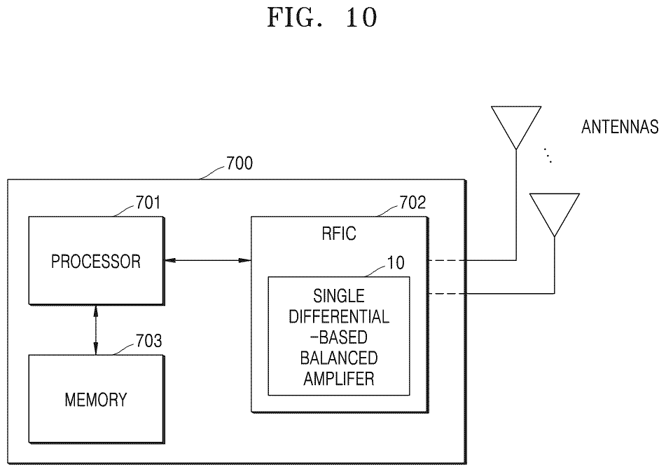

FIG. 10 is a block diagram of a wireless communication device 700 according to an embodiment.

FIG. 10 may be described with reference to FIGS. 2A through 9. Referring to FIG. 10, the wireless communication device 700 may include a processor 701, a radio-frequency integrated circuit (RFIC) 702, and a memory 703.

The processor 701 controls overall operations of the wireless communication device 700. For example, the processor 701 may transceive signals via the RFIC 702. In addition, the processor 701 may write and read data to and from the memory 703. In addition, the processor 701 may perform functions of the protocol stacks required by the communication standards. For convenience of description, the processor 701, the RFIC 702, and the memory 703 are each expressed as one block, but the wireless communication device 700 according to the embodiment may include a plurality of processors, a plurality of RFICs, and a plurality of memories. The processor 701 may control the wireless communication device 700 to perform operations according to various embodiments of the inventive concept.

The RFIC 702 may perform functions for transceiving signals. For example, the RFIC 702 may perform a conversion function between a baseband signal and a bit string according to a physical layer standard of a system. For example, during data transmission, the RFIC 702 may generate complex symbols by encoding and modulating a transmission bit string. In addition, when receiving data, the RFIC 702 may restore a received bit string by using demodulation and decoding of a baseband signal. In addition, the RFIC 702 may upwardly convert the baseband signal into an RF band signal, and may downwardly convert the RF band signal received via the antenna into the baseband signal. For example, the RFIC 702 may include a transmission filter, a receiving filter, an amplifier, a mixer, an oscillator, a digital-to-analog converter (DAC), an analog-to-digital converter (ADC), etc.

The RFIC 702 may include the single differential-based balanced amplifier 10 according to embodiments of the inventive concept. For convenience of descriptions, the single differential-based balanced amplifier 10 (or any of 10′ to 10^{V}) is illustrated as one block, but the RFIC 702 according to embodiments of the inventive concept may include a plurality of single differential-based balanced amplifiers 10. The RFIC 702 may transmit signals in various frequency bands, such as LTE, 5G, 6G, and Wi-Fi by using the single differential-based balanced amplifier 10 according to embodiments of the inventive concept.

The memory 703 may store data, such as a basic program, an application program, and setting information, for the operation of the wireless communication device 700. The memory 703 may include a volatile memory, a non-volatile memory, or a combination thereof. The memory 703 may provide stored data to the processor 701 according to the request of the processor 701.

Examples of the wireless communication device 700 may include at least one of a smart phone, a tablet PC, a mobile phone, a video phone, an e-book reader, a desktop PC, a laptop PC, a netbook computer, a personal digital assistant (PDA), a portable multimedia player (PMP), an MP3 player, a medical device, a camera, and a wearable device. Further examples of the wireless communication device 700 may include at least one of a TV set, a digital video disk (DVD) player, an audio device, a refrigerator, an air conditioner, a vacuum cleaner, an oven, a microwave, a washing machine, an air cleaner, a set-top box, a home automation control panel, a security control panel, a media box (for example, Samsung HomeSync™, Apple TV™, or Google TV™), a game console (for example, Xbox™ or PlayStation™), an electronic dictionary, an electronic key, a camcorder, and an electronic picture frame. Still further examples of the wireless communication device 700 may include at least one of various medical devices (for example, various portable medical measurement devices (a blood glucose meter, a heart rate meter, a blood pressure meter, a body temperature meter, or the like), magnetic resonance angiography (MRA), magnetic resonance imaging (MRI), computed tomography (CT), a camera, or an ultrasonic device, a navigation device, a global navigation satellite system (GNSS), an event data recorder (EDR), a flight data recorder (FDR), an automotive infotainment device, electronic equipment for ships (for example, a marine navigation device, a gyro compasses, or the like), avionics, a security device, a head unit for vehicles, an industrial or household robot, a drone, an automated teller machine (ATM) in financial institutions, point of sales (POS) in stores, and Internet of Things (IoT) devices (for example, a light bulb, various sensors, a sprinkler device, a fire alarm, a thermostat, a street light, a toaster, exercise equipment, a hot water tank, a heater, a boiler, etc.). In addition, the wireless communication device 700 may include various types of multimedia systems capable of communication functions.

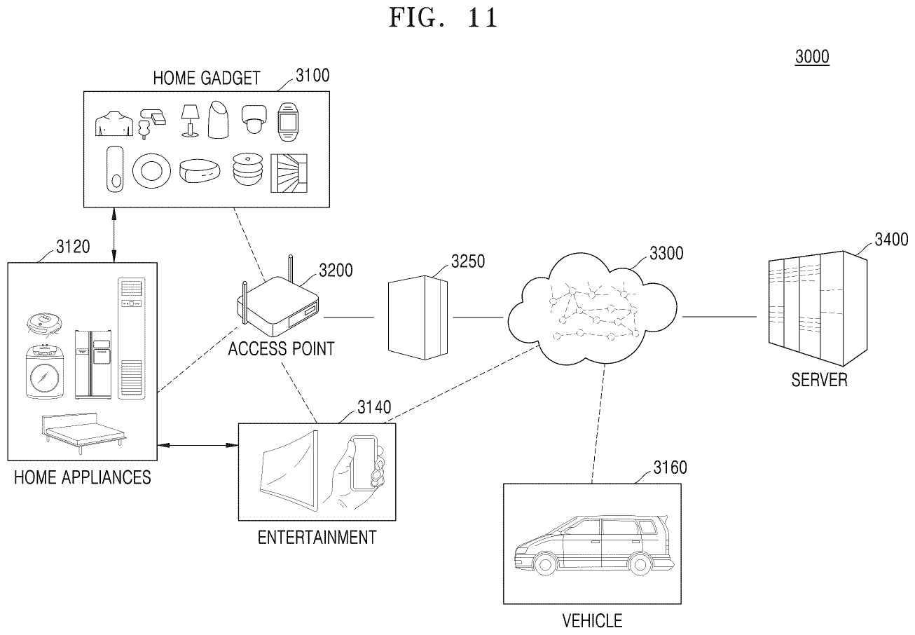

FIG. 11 is a conceptual diagram of an Internet of Things (IoT) network system, to which the embodiments of the inventive concept are applied.

Referring to FIG. 11, the IoT network system 3000 may include a plurality of IoT devices 3100, 3120, 3140, and 3160 an access point 3200, a gateway 3250, a wireless network 3300, and a server 3400. The IoT may be referred to as a network of objects using wired/wireless communication.

Each of the plurality of IoT devices 3100, 3120, 3140, and 3160 may form a group according to characteristics thereof. For example, the plurality of IoT devices 3100, 3120, 3140, and 3160 may be grouped into a home gadget group 3100, a home appliance/furniture group 3120, an entertainment group 3140, a vehicle group 3160, etc. The plurality of IoT devices 3100, 3120, and 3140 may be connected to a communication network or other IoT devices via the access point 3200. The access point 3200 may be embedded in one IoT device. The gateway 3250 may change a protocol so that the access point 3200 is connected to an external wireless network. The plurality of IoT devices 3100, 3120, and 3140 may be connected to the external communication network via the gateway 3250. The wireless network 3300 may include an internet and/or a public network. The plurality of IoT devices 3100, 3120, 3140, and 3160 may be connected to the server 3400 which provides a certain service via the wireless network 3300, and a user may use the service by using at least one of the plurality of IoT devices 3100, 3120, 3140, and 3160.

According to embodiments of the inventive concept, each of the plurality of IoT devices 3100, 3120, 3140, and 3160 may include one or more single differential-based balanced amplifiers 10 to 10^{V} described above. In this manner, the plurality of IoT devices 3100, 3120, 3140, and 3160 may include a sufficient number of single differential-based balanced amplifiers, the transmission/reception performance thereof may be improved, and may provide safe and high-quality services to the user.

In the embodiments described above, constituent components according to the technical idea of the inventive concept have been described by using terms, such as first, second, and third. However, the terms, such as first, second, and third may be used to differentiate the constituent components from each other, and may not limit the inventive concept. For example, the terms, such as first, second, and third may not connote a sequence or numerical meaning of an arbitrary type. In the embodiments described above, the constituent components according to embodiments have been referred to by using blocks. The blocks may be implemented as various hardware devices, such as an integrated circuit (IC), an application specific IC (ASIC), a field programmable gate array (FPGA), and a complex programmable logic device (CPLD), firmware driven in hardware devices, software such as an application, or a combination of hardware devices and software. In addition, the blocks may include circuits including semiconductor devices in the IC or circuits registered as intellectual property (IP).

While the inventive concept has been particularly shown and described with reference to embodiments thereof, it will be understood that various change in form and details may be made therein without departing from the spirit and scope of the following claims.

What is claimed is:

1. A single differential-based balanced amplifier comprising:
one differential amplifier configured to receive a first differential input signal and a second differential input signal having a phase difference of 180 degrees from the first differential input signal, and output a first differential output signal at a first output terminal and a second differential output signal at a second output terminal;
a phase delay circuit configured to receive the first differential output signal, and output a third differential output signal obtained by adjusting a phase of the first differential output signal relative to the second differential signal by 90 degrees; and
a hybrid coupler configured to receive the second differential output signal at a first port, receive the third differential output signal at a third port, and output, at a second port, an in-phase signal in which radio frequency (RF) power of the second differential output signal and the third differential output signal are combined in phase.

2. The single differential-based balanced amplifier of claim 1, wherein the hybrid coupler is a 90 degree branch line coupler.

3. The single differential-based balanced amplifier of claim 1, further comprising a transformer configured to receive a radio frequency (RF) signal, convert the RF signal into the first differential input signal and the second differential input signal, and output the first differential input signal and the second differential input signal to the differential amplifier.

4. The single differential-based balanced amplifier of claim 1,
further comprising a matching network circuit arranged between the differential amplifier and the hybrid coupler, and configured to form output impedance of the differential amplifier,
wherein the first differential output signal is transferred to the phase delay circuit via the matching network circuit, and the second differential output signal is transferred to the third port of the hybrid coupler via the matching network circuit.

5. The single differential-based balanced amplifier of claim 1,
wherein the matching network circuit comprises a first inductor, a second inductor, a third inductor, and a fourth inductor,
wherein the first inductor is connected between the first output terminal from which the first differential output signal of the differential amplifier is output and a first center node, the second inductor is connected between the second output terminal from which the second output differential signal of the differential amplifier is output and the first center node, the third inductor is connected between a second center node and an input node of the phase delay circuit, one end of the fourth inductor is connected to the second center node, and another end of the fourth inductor is connected to the third port of the hybrid coupler, and
wherein a supply voltage is applied to the first center node.

6. The single differential-based balanced amplifier of claim 1,
wherein the matching network circuit comprises a first inductor, a second inductor, a first capacitor, and a second capacitor,
wherein the first inductor is connected between the first output terminal and a first center node, the second inductor is connected between the second output terminal and the first center node, the first capacitor is connected between the first output terminal and an input node of the phase delay circuit, one end of the second capacitor is connected to the second output terminal, and another end of the second capacitor is connected to the third port of the hybrid coupler, and
wherein a supply voltage is applied to the first center node.

7. The single differential-based balanced amplifier of claim 5, wherein
the phase delay circuit comprises a first phase delay capacitor, a second phase delay capacitor, and a phase delay inductor,
wherein the first phase delay capacitor is connected between the input node of the phase delay circuit and a ground, one end of the second phase delay capacitor is connected to the first port of the hybrid coupler, another end of the hybrid coupler is connected to the ground, one end of the phase delay inductor is connected to the input node of the phase delay circuit, and another end of the phase delay inductor is connected to the first port of the hybrid coupler,
wherein the hybrid coupler comprises a first coupler capacitor, a second coupler capacitor, a first coupler inductor, and a second coupler inductor, and
wherein the first coupler capacitor is connected between the first port and the third port, the second coupler capacitor is connected between the second port and a fourth port, the first coupler inductor is connected between the third port and the fourth port, and the second coupler inductor is connected between the first port and the second port.

8. The single differential-based balanced amplifier of claim 6,
wherein the phase delay circuit comprises a first phase delay capacitor, a second phase delay capacitor, and a phase delay inductor,
wherein the first phase delay capacitor is connected between the input node of the phase delay circuit and a ground, one end of the second phase delay capacitor is connected to the first port of the hybrid coupler, another end of the hybrid coupler is connected to the ground, one end of the phase delay inductor is connected to the input node of the phase delay circuit, and another end of the phase delay inductor is connected to the first port of the hybrid coupler,
wherein the hybrid coupler comprises a first coupler capacitor, a second coupler capacitor, a first coupler inductor, and a second coupler inductor, and
wherein the first coupler capacitor is connected between the first port and the third port, the second coupler capacitor is connected between the second port and a fourth port, the first coupler inductor is connected between the third port and the fourth port, and the second coupler inductor is connected between the first port and the second port.

9. The single differential-based balanced amplifier of claim 1,
wherein the hybrid coupler comprises first through fourth coupler capacitors and first through sixth coupler inductors,
wherein the first coupler capacitor is connected between the first port and the third port, the second coupler capacitor is connected between the second port and a fourth port, one end of the third coupler capacitor is connected to one end of the sixth coupler inductor, another end of the third coupler capacitor is connected to the fourth port, one end of the fourth coupler capacitor is connected to one end of the fifth coupler inductor, and another end of the fourth coupler capacitor is connected to the second port, and
wherein one end of the first coupler inductor is connected to the third port, a supply power source is applied to the other end of the first coupler inductor, one end of the second coupler inductor is connected to the second port, the supply power source is applied to another end of the second coupler inductor, the third coupler inductor is connected between the fourth port and a ground, the fourth coupler inductor is connected between the second port and the ground, one end of the fifth coupler inductor may be connected to the third port, another end of the fifth coupler inductor is connected to one end of the fourth coupler capacitor, one end of the sixth coupler inductor is connected to the first port, and another end of the sixth coupler inductor is connected to the third coupler capacitor.

10. The single differential-based balanced amplifier of claim 1, wherein a fourth port of the hybrid coupler is isolated.

11. An operation method of a single differential-based balanced amplifier comprising a differential amplifier, a phase delay circuit, and a hybrid coupler, the method comprising:
applying to the differential amplifier a first differential input signal and a second differential input signal having a phase difference of 180 degrees from the first differential input signal;
outputting, by the differential amplifier, a first differential output signal and a second differential output signal;
outputting, by the phase delay circuit, a third differential output signal having an adjusted phase by 90 degrees from a phase of the first differential output signal; and
receiving, by the hybrid coupler including first through fourth ports, a third differential output signal at the first port, receiving the second differential output signal via the third port, and outputting an in-phase signal at the second port in which the second and third differential output signals are combined in phase.

12. The method of claim 11, wherein a phase difference between the second differential output signal and the third differential output signal is 90 degrees.

13. The method of claim 11, wherein the fourth port of the hybrid coupler is isolated.

14. A single differential-based balanced amplifier comprising:
one differential amplifier configured to receive a first differential input signal and a second differential input signal having a phase difference of 180 degrees from the first differential input signal, and output a first differential output signal at a first output terminal and a second differential output signal at a second output terminal;
a matching network circuit configured to form output impedance of the differential amplifier, transfer the first differential output signal to the phase delay circuit, and transfer the second differential output signal to the hybrid coupler;
a phase delay circuit configured to receive the first differential output signal from the differential amplifier via the matching network circuit, adjust the first differential output signal such that a phase of the first differential output signal is different from a phase of the second differential output signal by 90 degrees, and output a third differential output signal having the adjusted phase; and
a hybrid coupler configured to receive the second differential output signal at a first port, receive a third differential output signal at a third port, and output, at a second port, an in-phase signal in which RF power of the second differential output signal and the third differential output signal are combined in phase.

15. The single differential-based balanced amplifier of claim 14, further comprising a transformer configured to receive a radio frequency (RF) signal, convert the RF signal into the first differential input signal and the second differential input signal, and output the first differential input signal and the second differential input signal to the differential amplifier.

16. The single differential-based balanced amplifier of claim 14,
wherein the matching network circuit comprises a first inductor, a second inductor, a third inductor, and a fourth inductor,
wherein the first inductor is connected between the first output terminal from which the first differential output signal of the differential amplifier is output and a first center node, the second inductor is connected between the second output terminal from which the second output differential signal of the differential amplifier is output and the first center node, the third inductor is connected between a second center node and an input node of the phase delay circuit, one end of the fourth inductor is connected to the second center node, and another end of the fourth inductor is connected to the third port of the hybrid coupler, and
wherein a supply voltage is applied to the first center node.

17. The single differential-based balanced amplifier of claim 14,
wherein the matching network circuit comprises a first inductor, a second inductor, a first capacitor, and a second capacitor,
wherein the first inductor is connected between the first output terminal and a first center node, the second inductor is connected between the second output terminal and the first center node, the first capacitor is connected between the first output terminal and an input node of the phase delay circuit, one end of the second capacitor is connected to the second output terminal, and another end of the second capacitor is connected to the third port of the hybrid coupler, and
wherein a supply voltage is applied to the first center node.

18. The single differential-based balanced amplifier of claim 16,
wherein the phase delay circuit comprises a first phase delay capacitor, a second phase delay capacitor, and a phase delay inductor,
wherein the first phase delay capacitor is connected between the input node of the phase delay circuit and a ground, one end of the second phase delay capacitor is connected to the first port of the hybrid coupler, the other end of the hybrid coupler is connected to the ground, one end of the phase delay inductor is connected to the input node of the phase delay circuit, and the other end of the phase delay inductor is connected to the first port of the hybrid coupler,
wherein the hybrid coupler comprises a first coupler capacitor, a second coupler capacitor, a first coupler inductor, and a second coupler inductor, and
wherein the first coupler capacitor is connected between the first port and the third port, the second coupler capacitor is connected between the second port and a fourth port, the first coupler inductor is connected between the third port and the fourth port, and the second coupler inductor is connected between the first port and the second port.

19. The single differential-based balanced amplifier of claim 17,
wherein the phase delay circuit comprises a first phase delay capacitor, a second phase delay capacitor, and a phase delay inductor,
wherein the first phase delay capacitor is connected between the input node of the phase delay circuit and a ground, one end of the second phase delay capacitor is connected to the first port of the hybrid coupler, the other end of the hybrid coupler is connected to the ground, one end of the phase delay inductor is connected to the input node of the phase delay circuit, and the other end of the phase delay inductor is connected to the first port of the hybrid coupler,
wherein the hybrid coupler comprises a first coupler capacitor, a second coupler capacitor, a first coupler inductor, and a second coupler inductor, and
wherein the first coupler capacitor is connected between the first port and the third port, the second coupler capacitor is connected between the second port and a fourth port, the first coupler inductor is connected between the third port and the fourth port, and the second coupler inductor is connected between the first port and the second port.

20. The single differential-based balanced amplifier of claim 14, wherein a fourth port of the hybrid coupler is isolated.
